(19) United States
(12) Patent Application Publication
(10) Pub. No.: US 2024/0222232 A1
(43) Pub. Date: Jul. 4, 2024

(54) SEMICONDUCTOR DEVICE

(71) Applicant: Rohm Co., Ltd., Kyoto-shi (JP)

(72) Inventor: Akihiro KIMURA, Kyoto-shi (JP)

(21) Appl. No.: 18/604,939

(22) Filed: Mar. 14, 2024

Related U.S. Application Data
(63) Continuation of application No. PCT/JP2022/033566, filed on Sep. 7, 2022.

(30) Foreign Application Priority Data
Sep. 30, 2021 (JP) 2021-160665

(51) Int. Cl. H01L 23/495; H01L 23/00; H01L 25/16

(52) U.S. Cl. CPC H01L 23/49513; H01L 23/49517; H01L 23/49562; H01L 24/32; H01L 24/73; H01L 25/16; H01L 24/48; H01L 2224/32245; H01L 2224/48137; H01L 2224/73265; H01L 2924/12032; H01L 2924/13091

(57) ABSTRACT

A semiconductor device includes a substrate, a lead, and a semiconductor element. The substrate has an obverse surface facing in a thickness direction. The lead includes a die pad bonded to the substrate and a terminal connected to the pad. The semiconductor element is bonded to the pad. The bonding layer is disposed between the obverse surface and the pad. The obverse surface includes a first edge extending in a first direction crossing the thickness direction and a second edge extending in a second direction crossing the thickness direction and the first direction. As viewed in the thickness direction, the terminal protrudes outward from the obverse surface relative to the first edge. The distance from the first edge to the bonding layer in the second direction is shorter than the distance from the second edge to the bonding layer in the first direction.

### TECHNICAL FIELD

The present disclosure relates to semiconductor devices, and more particularly, to a semiconductor device including a substrate and a lead bonded to the substrate.

### BACKGROUND ART

JP-A-2014-207430 discloses an example of a semiconductor device. The semiconductor device includes a heat dissipating member, a lead bonded to the heat dissipating member, and a semiconductor element bonded to the lead. The lead includes an island portion to which the semiconductor element is bonded and a terminal portion connected to the island portion. The semiconductor device includes an adhesive layer interposed between the heat dissipating member and the island portion. The lead is hence bonded to the heat dissipating member via the adhesive layer.

In the semiconductor device disclosed in JP-A-2014-207430, heat from the semiconductor elements causes thermal expansion and contraction of the lead. As the coefficient of linear expansion is higher for the lead than for the heat dissipating member, thermal strain occurs in the lead. As a result, thermal stress develops at the bonding interface between the heat dissipating member and the lead. The thermal stress in the lead tends to concentrate at the boundary between the island portion and the terminal portion. This can cause a crack to form at the outer edge of the bonding layer and propagate into the heat dissipating member through the region nearest to the boundary. Such a crack can cause the heat dissipating member to rupture. It is therefore desirable to take measures for preventing the formation of a crack propagating to the heat dissipating member.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2, with the sealing resin shown as transparent.

FIG. 4 is a bottom view of the semiconductor device shown in FIG. 1.

FIG. 5 is a front view of the semiconductor device shown in FIG. 1.

FIG. 6 is a right-side view of the semiconductor device shown in FIG. 1.

FIG. 7 is a sectional view taken along line VII-VII in FIG. 3.

FIG. 8 is a sectional view taken along line VIII-VIII in FIG. 3.

FIG. 9 is a partially enlarged view of FIG. 8.

FIG. 10 is a partially enlarged view of FIG. 3, showing the first lead.

FIG. 11 is a sectional view taken along line XI-XI in

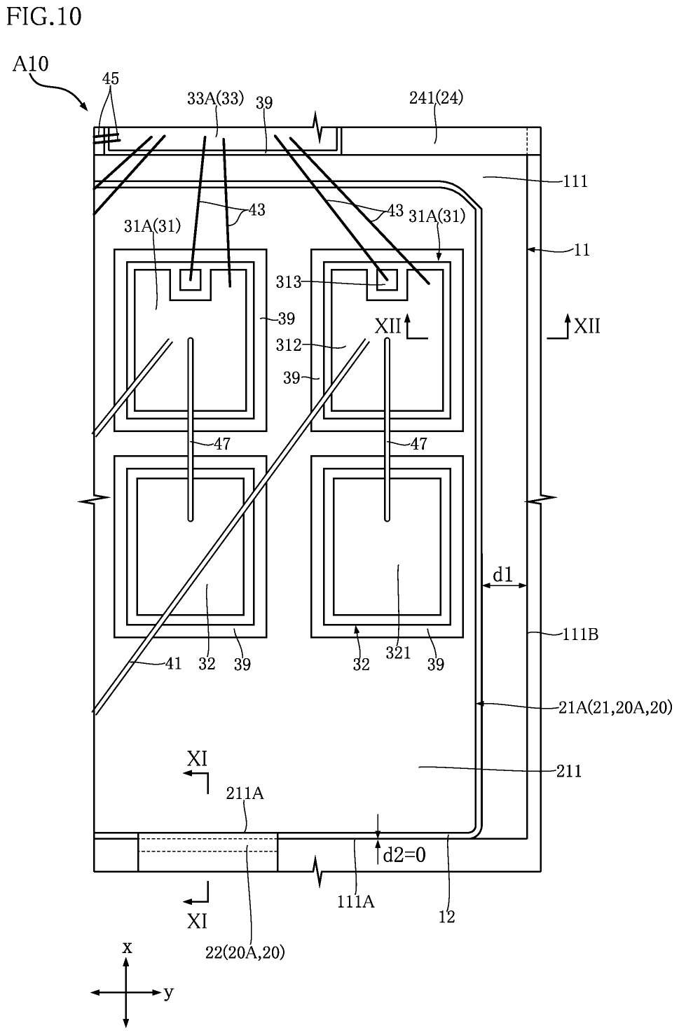

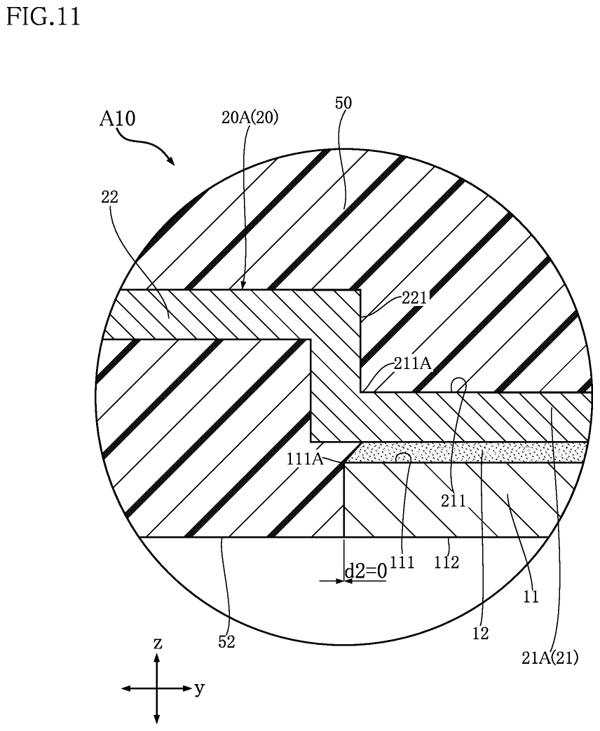

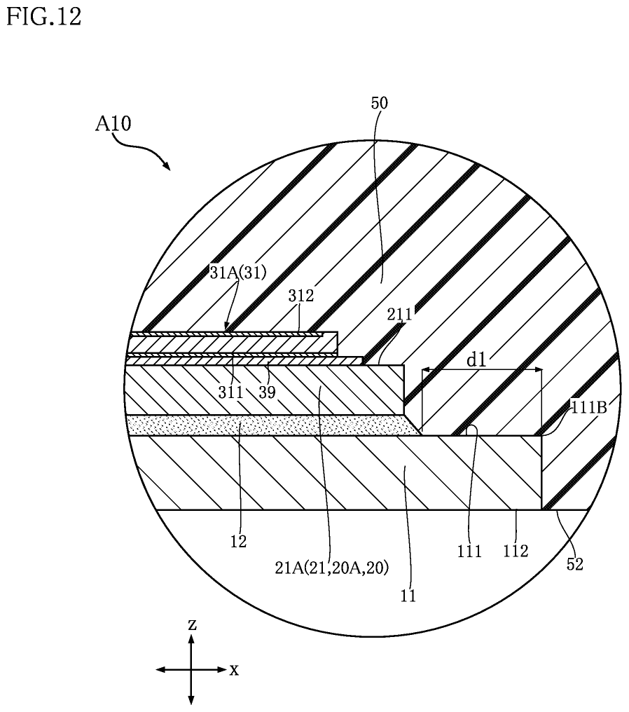

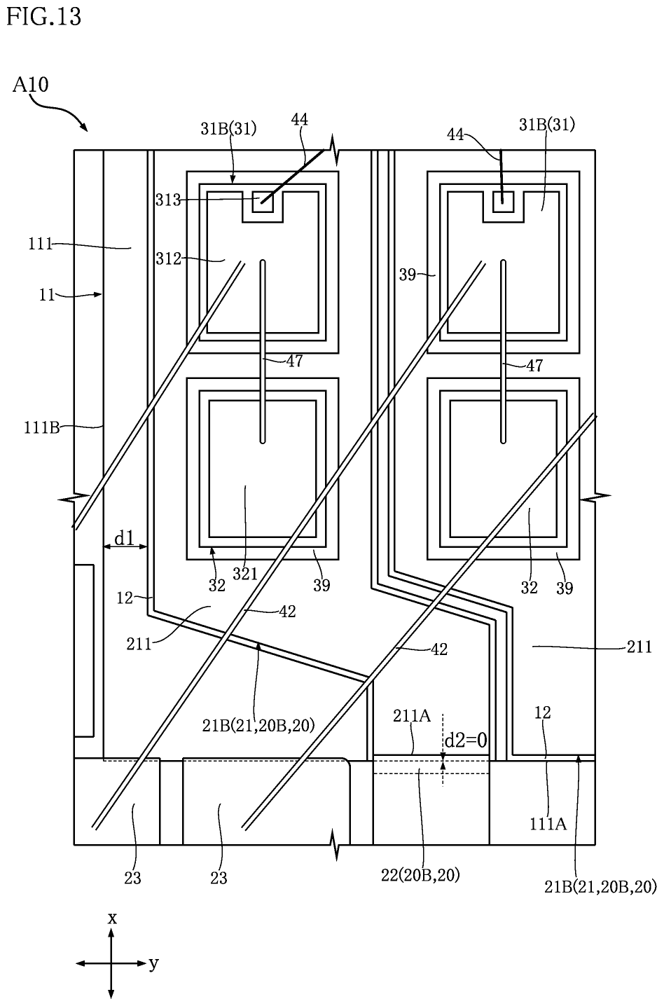

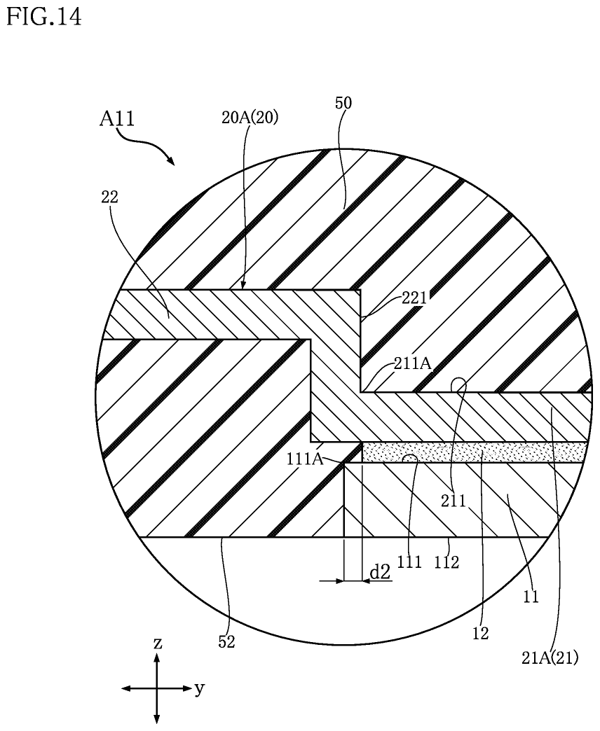

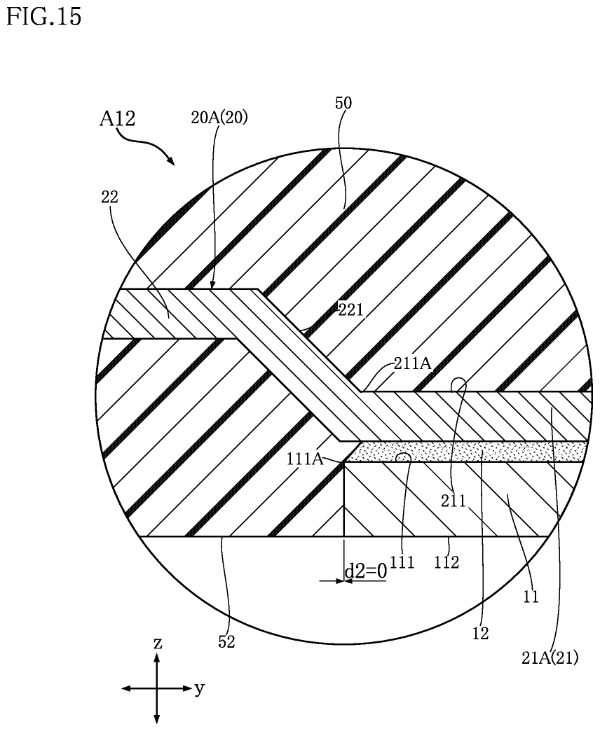

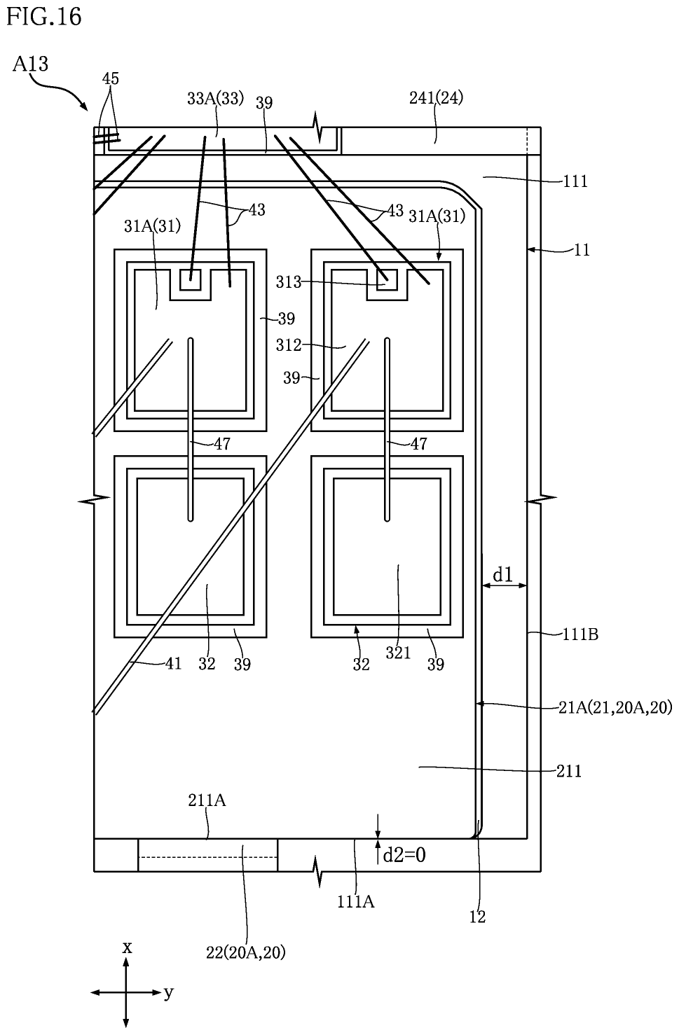

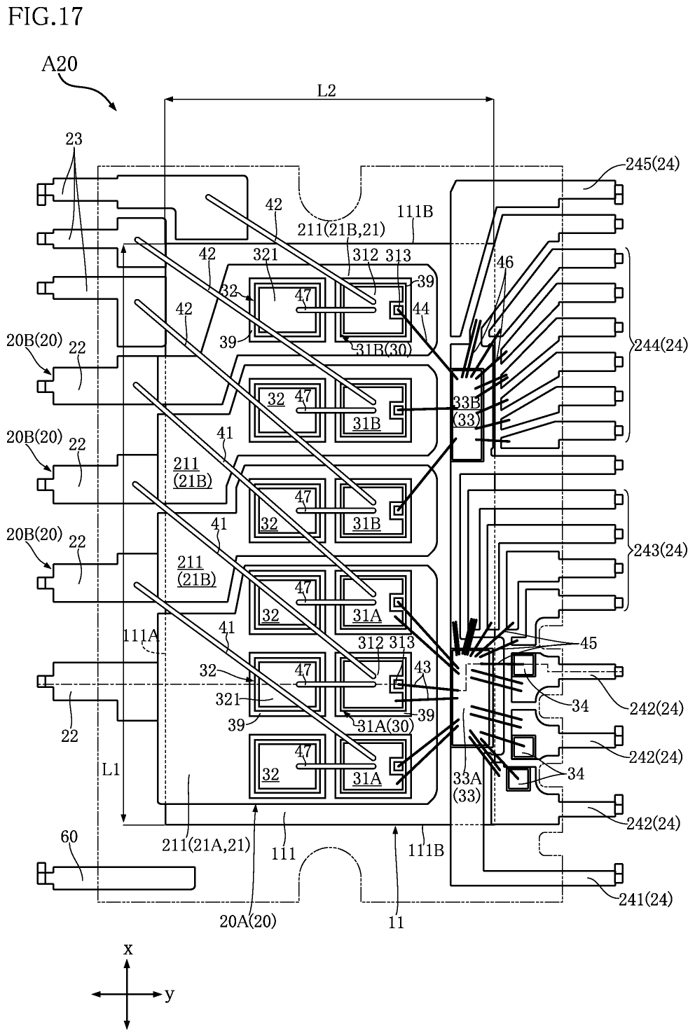

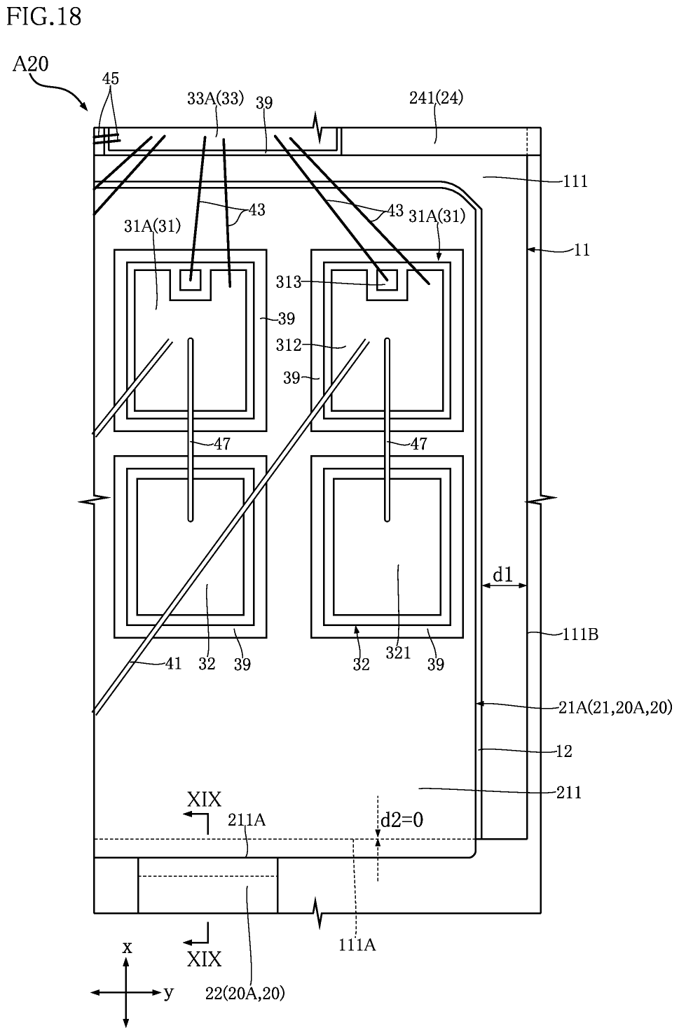

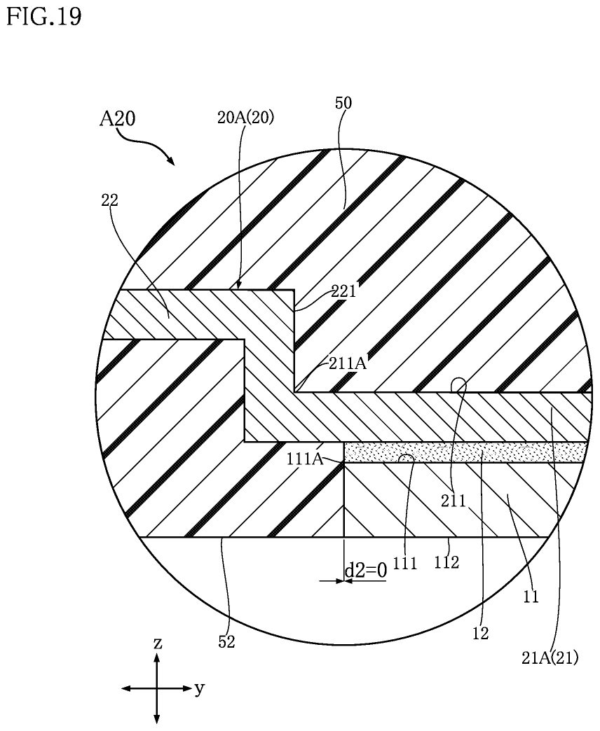

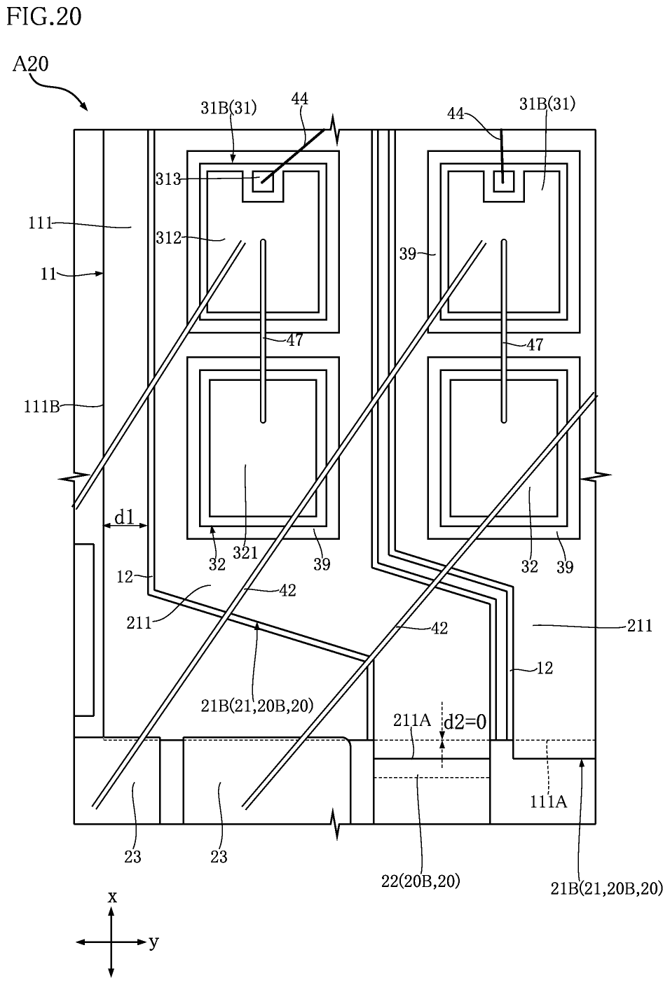

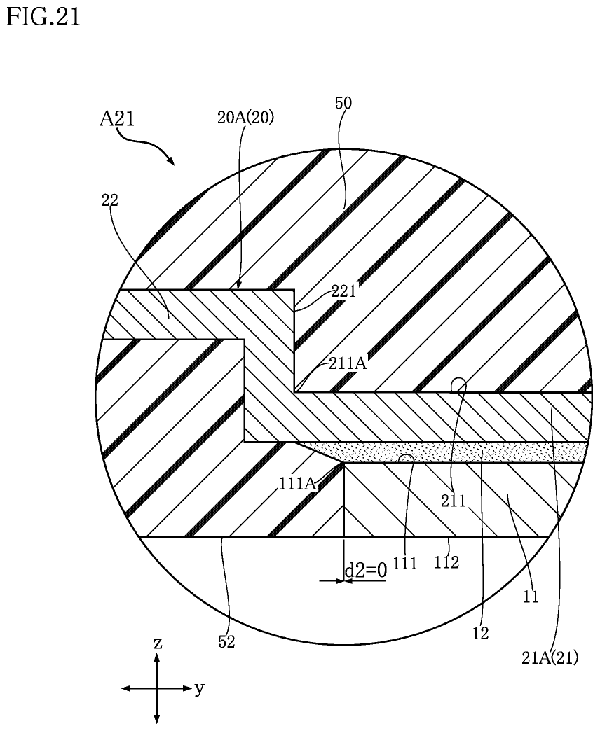

FIG. 10.

FIG. 12 is a sectional view taken along line XII-XII in FIG. 10.

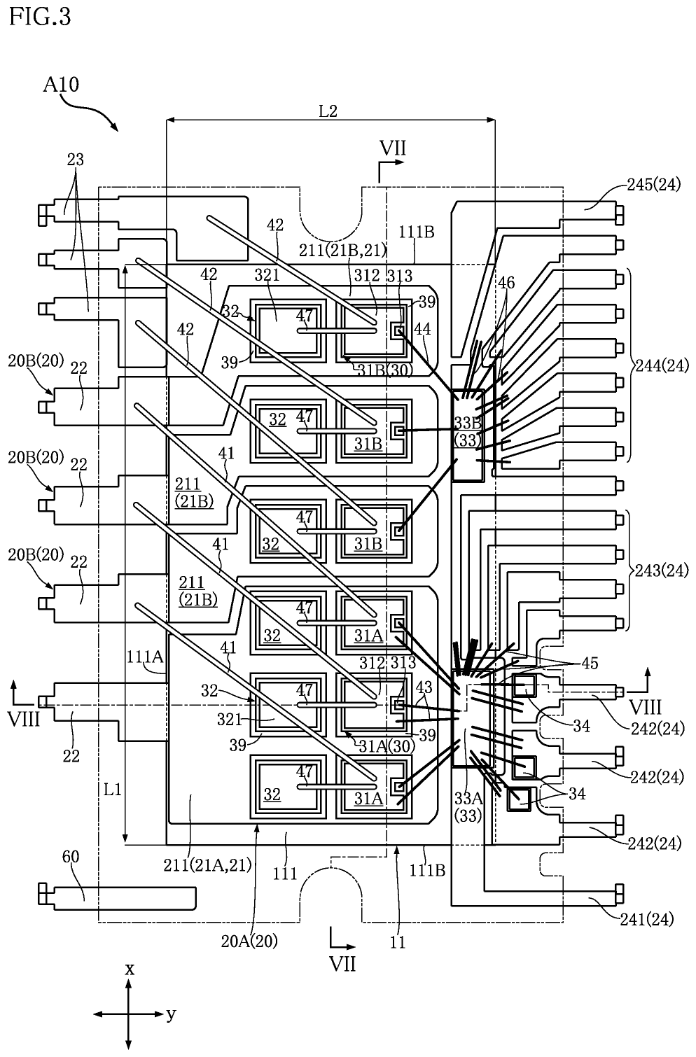

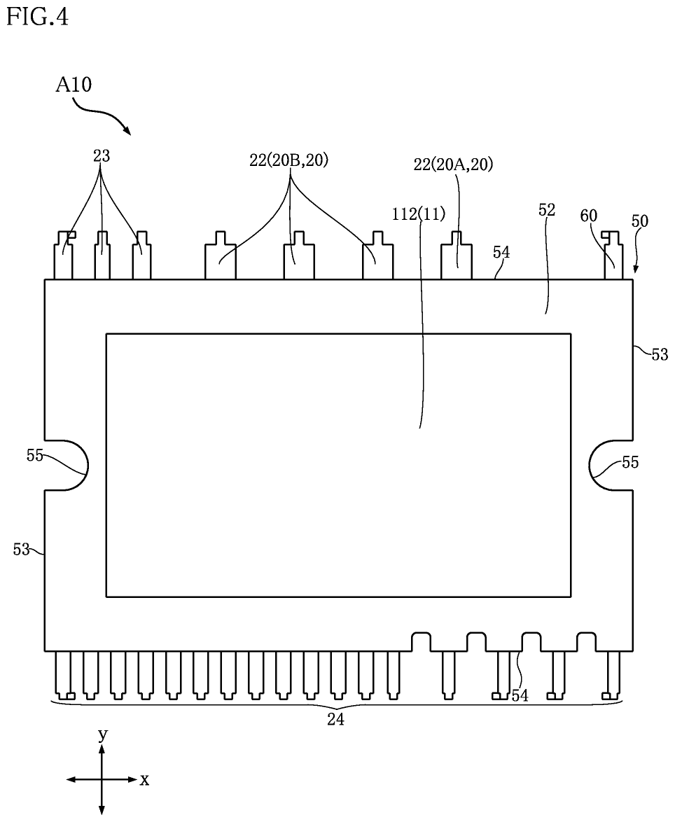

FIG. 13 is a partially enlarged view of FIG. 3, showing a plurality of second leads.

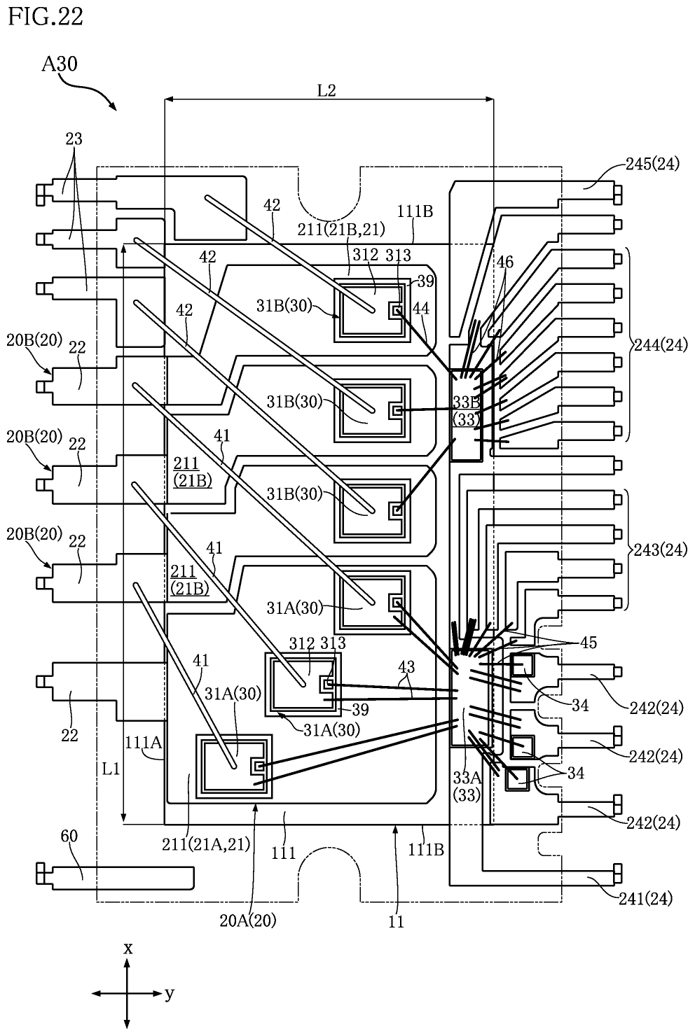

FIG. 14 is an enlarged sectional view, corresponding to FIG. 11, showing a portion of a semiconductor device according to a first variation of the first embodiment of the present disclosure.

FIG. 15 is an enlarged sectional view, corresponding to FIG. 11, showing a portion of a semiconductor device according to a second variation of the first embodiment of the present disclosure.

FIG. 16 is an enlarged plan view, corresponding to FIG. 10, showing a portion of a semiconductor device according to a third variation of the first embodiment of the present disclosure.

FIG. 17 is a plan view of a semiconductor device according to a second embodiment of the present disclosure, with the sealing resin shown as transparent.

FIG. 18 is a partially enlarged view showing the first lead of FIG. 17.

FIG. 19 is a sectional view taken along line XIX-XIX in FIG. 18.

FIG. 20 is a partially enlarged view of FIG. 17, showing a plurality of second leads.

FIG. 21 is an enlarged sectional view, corresponding to FIG. 19, showing a portion of a semiconductor device according to a variation of the second embodiment of the present disclosure.

FIG. 22 is a plan view of a semiconductor device according to a third embodiment of the present disclosure, with the sealing resin shown as transparent.

### DETAILED DESCRIPTION OF EMBODIMENTS

The following describes modes for carrying out the present disclosure with reference to the accompanying drawings.

### First Embodiment

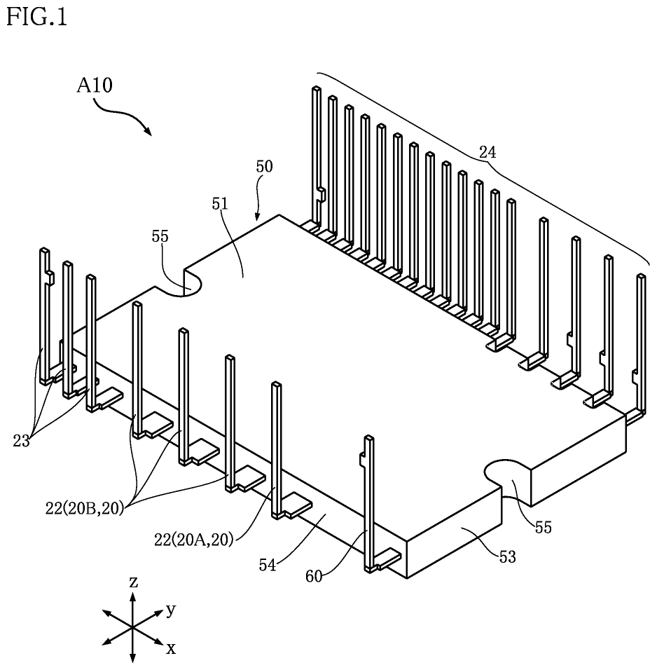

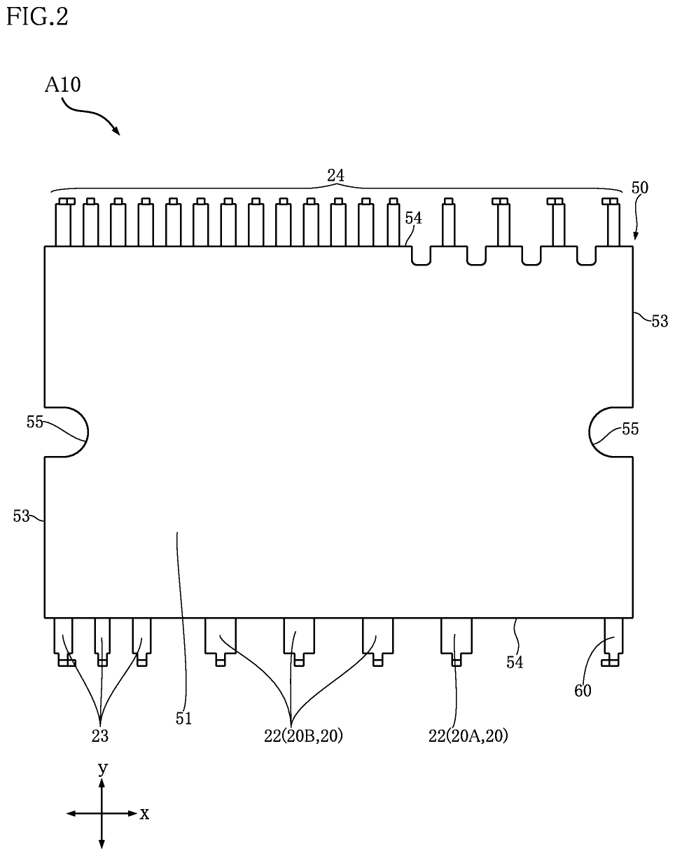

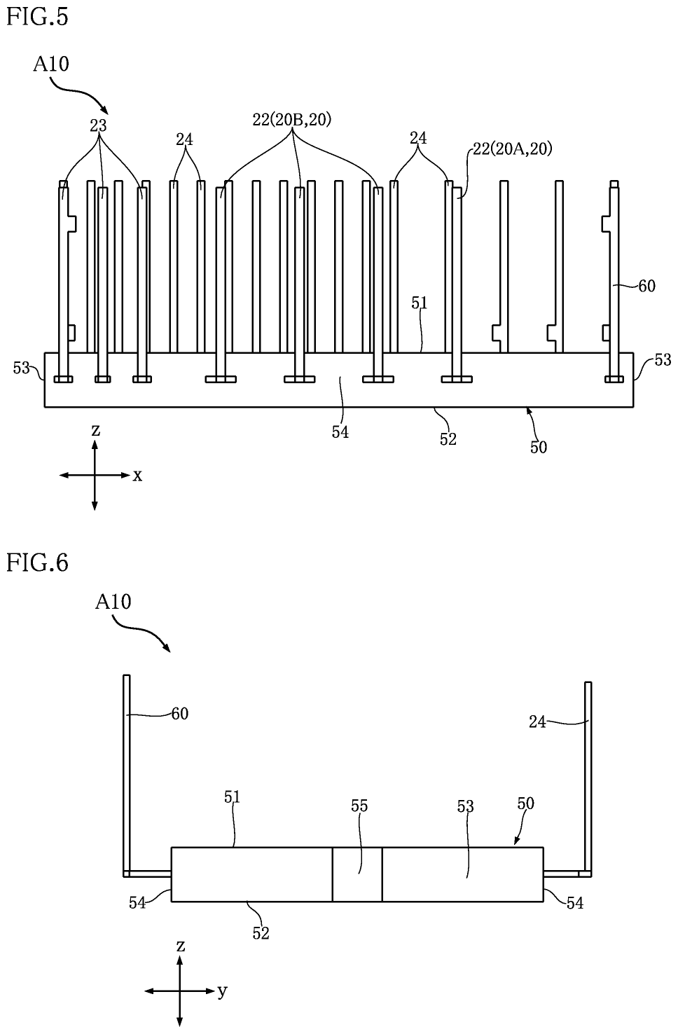

With reference to FIGS. 1 to 13, a semiconductor device A10 according to a first embodiment of the present disclosure will be described. The semiconductor device A10 includes a substrate 11, a bonding layer 12, a plurality of leads 20, a plurality of ground terminals 23, a plurality of semiconductor elements 31, a plurality of protection elements 32, a conductive bonding layer 39, a plurality of first wires 41, a plurality of second wires 42, and a sealing resin 50. The semiconductor device A10 also includes a plurality of control terminals 24, a plurality of ICs (integrated circuits) 33, a plurality of diodes 34, a plurality of third wires 43, a plurality of fourth wires 44, a plurality of fifth wires 45, a plurality of sixth wires 46, a plurality of seventh wires 47, and a dummy terminal 60. For convenience of description, FIG. 3 shows the sealing resin 50 as transparent. In FIG. 3, the sealing resin 50 is indicated by phantom lines (two-dot-dash lines). FIG. 3 also shows lines VII-VII and VIII-VIII in dot-dash lines.

In the description of the semiconductor device A10, the thickness direction of the substrate 11 is referred to as a “thickness direction z”. A direction orthogonal to the thickness direction z is referred to as a “first direction x”. The direction orthogonal to the thickness direction z and the first direction x is referred to as a “second direction y”.

The semiconductor device A10 converts direct-current power received at a first lead 20A, which is one of the plurality of leads 20 (detailed later), and the ground alternating-current power by the terminals 23 into semiconductor elements 31. The resulting alternating-current power is outputted from a plurality of second leads 20B, which are a subset of the plurality of leads 20 (detailed later), in three different phases (U phase, V phase, and W phase). In the semiconductor device A10, the ICs 33 drive the semiconductor elements 31. That is, the semiconductor device A10 is an intelligent power module (IPM). The semiconductor device A10 can be used for a power supply circuit for driving a three-phase alternating-current motor, for example.

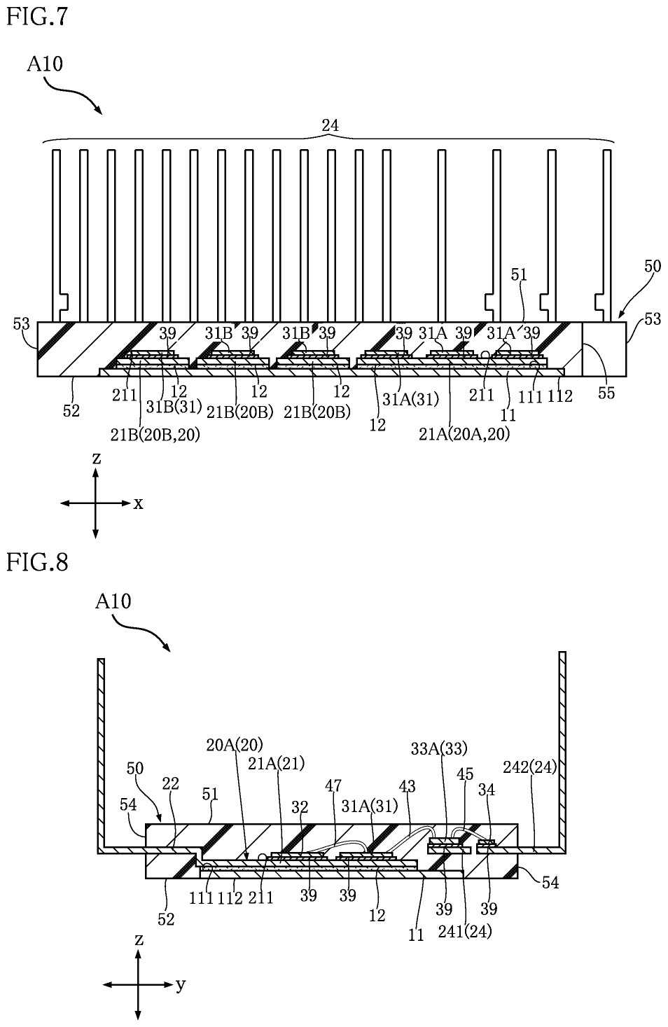

As shown in FIGS. 3 and 7, the substrate 11 supports the leads 20. The substrate 11 is electrically insulating. The substrate 11 is made of a ceramic material containing alumina (A1₂O₃), for example. Preferably, the substrate 11 is made of a material with a relatively high thermal conductivity. As shown in FIG. 7, the substrate 11 has an obverse surface 111 and a reverse surface 112. The obverse surface 111 faces in the thickness direction z. The reverse surface 112 faces away from the obverse surface 111 in the thickness direction z. As shown in FIGS. 4, 7, and 8, the substrate 11 is covered with the sealing resin 50 except at the reverse surface 112.

As shown in FIG. 3, the obverse surface 111 has a first edge 111A and a pair of second edges 111B. The first edge 111A and the pair of second edges 111B are portions of the outer edge of the obverse surface 111. The first edge 111A extends in the first direction x. The second edges 111B extend in the second direction y and are spaced apart from each other in the first direction x. The second edges 111B are connected to the opposite ends of the first edge 111A. The first edge 111A has a length L1, and the second edges 111B have a length L2, where the length L1 is longer than the length L2. That is, the substrate 11 is longer in the first direction x.

The plurality of leads 20 are formed from one lead frame, along with the ground terminals 23, the control terminals 24, and the dummy terminal 60. The lead frame is made of a material containing copper (Cu) or a copper alloy. Hence, the composition of the leads 20, the ground terminals 23, the control terminals 24, and the dummy terminal 60 includes copper. In other words, these components contain copper.

As shown in FIG. 3, the leads 20 include the first lead 20A and the plurality of second leads 20B. Each lead 20 includes a die pad portion 21 and a terminal portion 22.

As shown in FIGS. 3 and 7, the die pad portions 21 are bonded to the obverse surface 111 of the substrate 11. The die pad portions 21 are covered with the sealing resin 50. The die pad portions 21 of the leads 20 include a first pad portion 21A and a plurality of second pad portions 21B. The first pad portion 21A is the die pad portion 21 of the first lead 20A. The second pad portions 21B are the die pad portions 21 of the second leads 20B. The plurality of second pad portions 21B are disposed next to the first pad portion 21A in the first direction x.

As shown in FIG. 7, each die pad portion 21 has a mounting surface 211. The mounting surface 211 faces the same side in the thickness direction z as the obverse surface 111. Each semiconductor element 31 is bonded either to the mounting surface 211 of the first pad portion 21A or to the mounting surface 211 of a second pad portion 21B.

As shown in FIGS. 10 and 13, the mounting surface 211 of each die pad portion 21 has a connecting edge 211A. The connecting edge 211A is a portion of the outer edge of the mounting surface 211. The connecting edge 211A is the edge nearest to the first edge 111A of the obverse surface 111 of the substrate 11 and extends in the first direction x. In the semiconductor device A10, the die pad portions 21 are enclosed in the outer edge of the obverse surface 111. Hence, the connecting edges 211A overlap with the obverse surface 111 as viewed in the thickness direction z.

As shown in FIGS. 3 and 8, each terminal portion 22 is connected to the relevant die pad portion 21. As shown in FIGS. 2, 4, and 5, each terminal portion 22 is partly exposed from the sealing resin 50. As viewed in the thickness direction z, each terminal portion 22 protrudes outward from the obverse surface 111 of the substrate 11 relative to the first edge 111A. In the semiconductor device A10, each terminal portion 22 overlaps with the first edge 111A of the obverse surface 111 as viewed in the thickness direction z. The terminal portion 22 of the first lead 20A corresponds to a P terminal (positive electrode) for input of direct-current power, which will be converted to alternating-current power. The terminal portions 22 of the second leads 20B are for output of the three-phase alternating-current power as converted by the semiconductor elements 31.

As shown in FIG. 11, each terminal portion 22 has a connecting surface 221. The connecting surface 221 is connected to the connecting edge 211A of the mounting surface 211 of the die pad portion 21. The connecting surface 221 contains a first direction x as an in-plane direction (a direction parallel to the surface). In the semiconductor device A10, the connecting surface 221 is orthogonal to the mounting surface 211.

As shown in FIGS. 7 and 8, the bonding layer 12 is interposed between the obverse surface 111 of the substrate 11 and the die pad portions 21 of the leads 20. The bonding layer 12 bonds the die pad portions 21 of the leads 20 to the obverse surface 111. The bonding layer 12 is electrically insulating and made of a material containing resin. The resin may be an epoxy resin, for example.

In other examples, the bonding layer 12 may be made of a material containing metal. In such examples, the bonding layer 12 may be solder. Such examples require a base layer (not shown) between the obverse surface 111 and the bonding layer 12. The base layer contains a metallic element, which may be silver (Ag), for example. In one example, the base layer may be formed by applying paste of silver resinate to the obverse surface 111, followed by sintering.

As shown in FIGS. 10 and 13, for the obverse surface 111 of the substrate 11, let d1 denote the distance from each second edge 111B to the outer edge of the bonding layer 12 in the second direction y, and d2 denote the distance from the first edge 111A to the outer edge of the bonding layer 12 in the first direction x. The distance d2 is shorter than the distance d1. Note that each of the distance d1 and the distance d2 is the shortest one among all the applicable distances. The outer edge of the bonding layer 12 refers to the edge nearest to the obverse surface 111 in the thickness direction z. Thus, any edge of the bonding layer 12 located farther from the obverse surface 111 is not considered as a portion of the outer edge, even if such an edge is the outermost edge as viewed in the thickness direction z. As shown in FIG. 11, in the semiconductor device A10, the bonding layer 12 is in contact with the first edge 111A of the obverse surface 111. Hence, the distance d2 is equal to zero in the semiconductor device A10.

As shown in FIG. 3, the ground terminals 23 are spaced apart from the substrate 11 and the leads 20. At least one of the ground terminals 23 is located opposite the first pad portion 21A in the first direction x with the plurality of second pad portions 21B interposed therebetween. The plurality of ground terminals 23 are located opposite the first lead 20A with the second leads 20B interposed there between. The ground terminals 23 are supported by the sealing resin 50. As shown in FIGS. 2, 4, and 5, each ground terminal 23 is partly exposed from the sealing resin 50. The ground terminals 23 correspond to N terminals (negative electrodes) for input of direct-current to be converted.

As shown in FIGS. 3 and 7, the semiconductor elements 31 are bonded to the mounting surfaces 211 of the die pad portions 21 of the leads 20. The semiconductor elements 31 include a plurality of first elements 31A and a plurality of second elements 31B. The first elements 31A are bonded to the mounting surface 211 of the first pad portion 21A, among the die pad portions 21 of the leads 20. In the semiconductor device A10, the first elements 31A are arranged along the first direction x. The second elements 31B are bonded to the mounting surfaces 211 of the second pad portions 21B, among the die pad portions 21 of the leads 20.

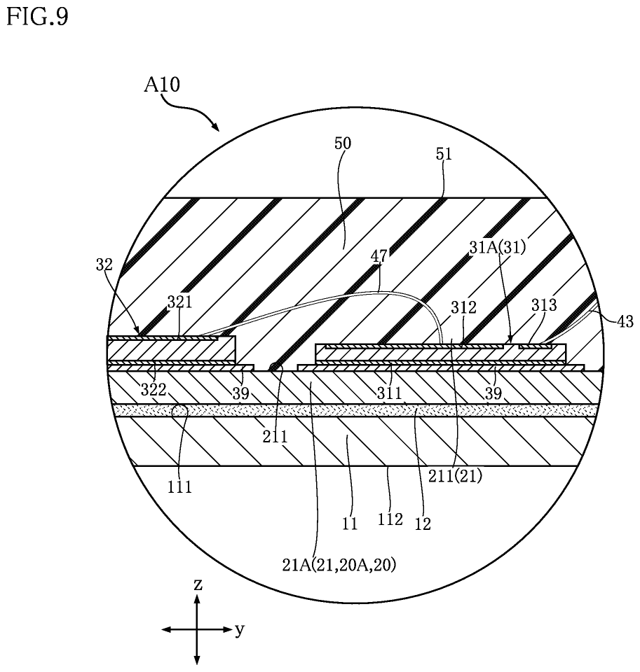

In one example, the semiconductor elements 31 are metal-oxide-semiconductor field-effect transistors (MOSFETs). In other examples, the semiconductor elements 31 may be switching elements, such as insulated gate bipolar transistors (IGBTs), or diodes. The following description is directed to the semiconductor device A10 where the semiconductor elements 31 are n-channel, vertical type MOSFETs. Each semiconductor element 31 includes a compound semiconductor substrate. The composition of the compound semiconductor substrate includes silicon carbide (SiC). As shown in FIG. 9, each semiconductor element 31 includes a first electrode 311, a second electrode 312, and a gate electrode 313.

As shown in FIG. 9, the first electrode 311 faces the mounting surface 211 of the die pad portion 21 of the relevant lead 20. The first electrode 311 conducts the current corresponding to the power before conversion by the semiconductor element 31. That is, the first electrode 311 is the drain electrode of the semiconductor element 31.

As shown in FIG. 9, the second electrode 312 is located opposite the first electrode 311 in the thickness direction Z. The second electrode 312 conducts the current corresponding to the power after conversion by the semiconductor element 31. That is, the second electrode 312 is the source electrode of the semiconductor element 31. The second electrode 312 includes a plurality of plating layers of metal. The second electrode 312 includes a nickel (Ni) plating layer, and a gold (Au) plating layer deposited on the nickel plating layer. In another example, the second electrode 312 may include a nickel plating layer, a palladium (Pd) plating layer deposited on the nickel plating layer, and a gold plating layer deposited on the palladium plating layer.

As shown in FIG. 9, the gate electrode 313 is disposed on the same side as the second electrode 312 in the thickness direction z in spaced relation from the second electrode 312. The gate electrode 313 will receive the gate voltage applied for driving the semiconductor element 31. As shown in FIG. 10, the gate electrode 313 is smaller in area as viewed in the thickness direction z than the second electrode 312.

As shown in FIG. 7, the conductive bonding layer 39 bonds the die pad portions 21 of the leads 20 and the semiconductor elements 31. The first electrodes 311 of the first elements 31A are electrically bonded to the mounting surface 211 of the first pad portion 21A via the conductive bonding layer 39. The first electrodes 311 of the second elements 31B are electrically bonded to the mounting surfaces 211 for the respective second elements 31B via the conductive bonding layer 39. The conductive bonding layer 39 may be made of solder, for example.

As shown in FIGS. 3 and 8, the protection elements 32 are electrically bonded to the mounting surfaces 211 of the die pad portions 21 of the leads 20. The number of protection elements 32 bonded to each die pad portion 21 is equal to the number of the semiconductor elements 31 bonded to that die pad portion 21. The protection elements 32 may be Schottky barrier diodes, for example. The protection elements 32 are electrically connected to the semiconductor elements 31. Each protection element 32 is connected in parallel to one of the protection element 32 semiconductor elements 31. Each conducts the current that flows when the semiconductor element 31 connected in parallel to that protection element 32 is reversed-biased, preventing the current from flowing through the semiconductor element 31. That is, each protection element 32 is what is referred to as a freewheel diode. As shown in FIG. 9, each protection element 32 includes an upper-surface electrode 321 and a lower-surface electrode 322.

As shown in FIG. 9, the upper-surface electrode 321 is disposed on the side toward which the mounting surface 211 of the die pad portion 21 of the relevant lead 20 faces in the thickness direction z. The upper-surface electrode 321 corresponds to the anode electrode of the protection element 32.

As shown in FIG. 9, the lower-surface electrode 322 faces the mounting surface 211 of the die pad portion 21 of the relevant lead 20. The lower-surface electrode 322 corresponds to the cathode electrode of the protection element 32. The lower-surface electrode 322 of each protection element 32 is electrically bonded to the mounting surface 211 of the die pad portion 21 of the relevant lead 20 via the conductive bonding layer 39. Consequently, the lower-surface electrode 322 of each protection element 32 is electrically connected to the first electrode 311 of at least one semiconductor element 31.

As shown in FIG. 3, the protection elements 32 electrically bonded to the mounting surface 211 of the first pad portion 21A of the first lead 20A are arranged along the first direction x and spaced apart from the first elements 31A in the second direction y toward the terminal portion 22 of the first lead 20A.

As shown in FIG. 3, each first wire 41 is electrically bonded to the second electrode 312 of a first element 31A and the terminal portion 22 of a second lead 20B. This electrically connects the second electrodes 312 of the first elements 31A to the second leads 20B. Hence, the first electrode 311 of each second element 31B is electrically connected to the second electrode 312 of a first element 31A. The composition of the first wires 41 includes aluminum (Al). In a different example, the composition of the first wires 41 may include copper.

As shown in FIG. 3, each second wire 42 is electrically bonded to the second electrode 312 of a second element 31B and a ground terminal 23. This electrically connects the second electrodes 312 of the second elements 31B separately to the ground terminals 23. The composition of the second wires 42 includes aluminum. In a different example, the composition of the second wires 42 may include copper.

As shown in FIGS. 10 and 13, each seventh wire 47 is electrically bonded to the second electrode 312 of a semiconductor element 31 and the upper-surface electrode 321 of a protection element 32. Consequently, the upper-surface electrode 321 of each protection element 32 is electrically connected to the second electrode 312 of a semiconductor element 31.

In the semiconductor device A10, the first lead 20A, the first elements 31A, and the first wires 41 form a plurality of upper arm circuits. In addition, the second leads 20B, the second elements 31B, the second wires 42, and the ground terminals 23 from a plurality of lower arm circuits. The voltage applied to each gate electrode 313 is hence higher for the first elements 31A than for the second elements 31B. In the semiconductor device A10, a separate ground can be set for each lower arm circuit.

As shown in FIG. 3, the control terminals 24 are located opposite the terminal portions 22 of the leads 20 in the second direction y with the die pad portions 21 of the leads 20 interposed therebetween. Similarly to the ground terminals 23, the control terminal 24 are separated from the substrate 11 and supported by the sealing resin 50. As shown in FIGS. 2 and 4, each control terminal 24 is partly exposed from the sealing resin 50.

As shown in FIG. 3, the plurality of control terminals 24 include a pad portion 241, a plurality of power supply portions 242, a plurality of first control portions 243, a plurality of second control portions 244, and a dummy portion 245. The pad portion 241 is where the ICs 33 are mounted. The pad portion 241 is the ground of the ICs 33. The ICs 33 are located opposite the terminal portions 22 of the leads 20 in the second direction y with the die pad portions 21 of the leads 20 interposed therebetween. As viewed in the thickness direction z, the ICs 33 overlap with the obverse surface 111 of the substrate 11. The plurality of ICs 33 include a first IC 33A and a second IC 33B spaced apart from each other in the first direction x. The power supply portions 242 receive the supply of power, which is the source of the gate voltage for driving the first elements 31A. The first control portions 243 are used to input and output an electric signal for controlling the first IC 33A. The second control portions 244 are used to input and output an electric signal for controlling the second IC 33B. The dummy portion 245 is not electrically connected to the ICs 33.

As shown in FIG. 8, the first IC 33A is bonded to the pad portion 241 via the conductive bonding layer 39. As shown in FIG. 3, the first IC 33A is located closer than the second IC 33B to the first pad portion 21A of the first lead 20A. The first IC 33A applies the gate voltage to the gate electrodes 313 of the first elements 31A.

Similarly to the first IC 33A, the second IC 33B is bonded to the pad portion 241 via the conductive bonding layer 39. As shown in FIG. 3, the second IC 33B is located closer than the first IC 33A to the second leads 20B of the second pad portions 21B. The second IC 33B applies the gate voltage to the gate electrodes 313 of the second elements 31B.

As shown in FIG. 8, the diodes 34 are electrically bonded to the power supply portions 242 via the conductive bonding layer 39. The diodes 34 serve to prevent the reverse bias from being applied to the power supply portions 242 during the operation of the first elements 31A.

As shown in FIG. 3, the third wires 43 are electrically bonded to the first IC 33A and to the second electrode 312 and the gate electrode 313 of each first element 31A. This allows the gate voltage to be applied from the first IC 33A to the gate electrodes 313 of the first elements 31A. In addition, the ground for the gate voltage is set at the first IC 33A. The composition of the third wires 43 includes gold, for example.

As shown in FIG. 3, the fourth wires 44 are electrically bonded to the second IC 33B and to the gate electrodes 313 of the second elements 31B. This allows the gate voltage to be applied from the second IC 33B to the gate electrodes 313 of the second elements 31B. The composition of the fourth wires 44 includes gold, for example.

As shown in FIG. 3, the fifth wires 45 are electrically bonded to the first IC 33A and to the pad portion 241, the power supply portions 242, the diodes 34, and the first control portions 243. This electrically connects the pad portion 241, the power supply portions 242, the diodes 34, and the first control portions 243 to the first IC 33A. The composition of the fifth wires 45 includes gold, for example.

As shown in FIGS. 3, the sixth wires 46 are connected to the second IC 33B and to the pad portion 241 and the second control portions 244. This electrically connects the pad portion 241 and the second control portions 244 to the second IC 33B. The composition of the sixth wires 46 includes gold, for example.

As shown in FIG. 3, the dummy terminal 60 is spaced apart from the obverse surface 111 of the substrate 11 as viewed in the thickness direction z. The dummy terminal 60 is located opposite the terminal portions 22 of the second leads 20B in the first direction x with the terminal portion 22 of the first lead 20A interposed therebetween. As shown in FIGS. 2, 4, and 6, the dummy terminal 60 is partly exposed from the sealing resin 50.

As shown in FIGS. 7 and 8, the sealing resin 50 covers the semiconductor elements 31, the protection elements 32, and a portion of each lead 20. The sealing resin 50 is in contact with the obverse surface 111 of the substrate 11. In particular, the sealing resin 50 is in contact with the first edge 111A and the pair of second edges 111B of the obverse surface 111. The substrate 50 is electrically insulating. The sealing resin 50 is made of a material containing a black epoxy resin, for example. The sealing resin 50 has a top surface 51, a bottom surface 52, a pair of first side surfaces 53, a pair of second side surfaces 54, and a pair of recessed portions 55.

As shown in FIGS. 7 and 8, the top surface 51 faces the same side as the obverse surface 111 of the substrate 11 in the thickness direction z. As shown in FIGS. 7 and 8, the bottom surface 52 faces away from the top surface 51 in the thickness direction z. As shown in FIG. 4, the reverse surface 112 of the substrate 11 is exposed from the bottom surface 52.

As shown in FIGS. 2, 4 and 5, the first side surfaces 53 are spaced apart from each other in the first direction x. Each first side surface 53 is connected to the top surface 51 and the bottom surface 52.

As shown in FIGS. 2, 4 and 6, the second side surfaces 54 are spaced apart from each other in the second direction y. Each second side surface 54 is connected to the top surface 51 and the bottom surface 52. The terminal portions 22 of the leads 20, the ground terminals 23, and the dummy terminal 60 are partly exposed from one of the second side surfaces 54. The control terminals 24 are partly exposed from the other second side surface 54.

As shown in FIGS. 2, 4, and 6, the recessed portions 55 are recessed in the first direction x from the first side surfaces 53. Each recessed portion 55 extends from the top surface 51 through to the bottom surface 52 in the thickness direction z. Due to the presence of the recessed portions 55, the creepage distance along the sealing resin 50 is increased from the terminal portion 22 of the first lead 20A to the control terminals 24. Similarly, the creepage distance along the sealing resin 50 is also increased from the ground terminals 23 to the control terminals 24. This is desirable for improving the dielectric strength of the semiconductor device A10.

### First Variation of First Embodiment

The following describes a semiconductor device A11 according to a first variation of the semiconductor device A10 with reference to FIG. 14. FIG. 14 shows a portion corresponding to that shown in FIG. 11.

As shown in FIG. 14, in the semiconductor device A11, the bonding layer 12 is spaced apart from the first edge 111A of the obverse surface 111 of the substrate 11. Consequently, in the semiconductor device A11, the distance d2 from the first edge 111A to the outer edge of the bonding layer 12 in the second direction y is greater than zero as viewed in the thickness direction z.

### Second Variation of First Embodiment

The following describes a semiconductor device A12 according to a second variation of the semiconductor device A10 with reference to FIG. 15. FIG. 15 shows a portion corresponding to that shown in FIG. 11.

As shown in FIG. 15, in the semiconductor device A12, the terminal portion 22 of at least one lead 20 is configured such that the connecting surface 221 is inclined relative to the mounting surface 211 of the die pad portion 21. The connecting surface 221 is inclined to be increasing away from the mounting surface 211 in the second direction y with separation from the mounting surface 211 in the thickness direction z.

### Third Variation of First Embodiment

The following describes a semiconductor device A13 according to a third variation of the semiconductor device A10 with reference to FIG. 16. FIG. 16 shows a portion corresponding to that shown in FIG. 10.

As shown in FIG. 16, in the semiconductor device A13, the die pad portion 21 of at least one lead 20 is arranged such that the connecting edge 211A of the mounting surface 211 overlaps with the first edge 111A of the obverse surface 111 of the substrate 11 as viewed in the thickness direction Z.

The following describes the operation and effect of the semiconductor device A10.

The semiconductor device A10 includes a substrate 11 having an obverse surface 111, a lead 20 having a die pad portion 21 and a terminal portion 22, and a bonding layer 12 disposed between the obverse surface 111 and the die pad portion 21. The obverse surface 111 has a first edge 111A extending in the first direction x and a second edge 111B extending in the second direction y. As viewed in the thickness direction z, the terminal portion 22 protrudes outward from the obverse surface 111 relative to the first edge 111A. The distance d2 from the first edge 111A to the outer edge of the bonding layer 12 in the second direction y is shorter than the distance d1 from the second edge 111B to the outer edge of the bonding layer 12 in the first direction X.

In the lead 20, thermal strain tends to concentrate on the connecting edge 211A (see FIG. 10), which is the boundary between the die pad portion 21 and the terminal portion 22. Consequently, the resulting thermal stress occurring at the bonding interface between the substrate 11 and the lead 20 tends to concentrate along a portion of the outer edge of the bonding layer 12 relatively close to the connecting edge 211A. This often results in the propagation of a crack in the region of the substrate 11 located between such a portion of the outer edge of the bonding layer 12 and the outer edge of the obverse surface 111. In view of this, the semiconductor device A10 is configured as described above such that the substrate 11 has the reduced volume of the region where a crack tends to propagate. As a result, the propagation of a crack is less likely. The semiconductor device A10 can therefore prevent the formation of a crack propagating from the bonding interface between the substrate 11 and the lead 20 to the substrate 11.

The bonding layer 12 is in contact with the first edge 111A of the obverse surface 111. Thus, the distance d2 from the first edge 111A to the outer edge of the bonding layer 12 in the second direction y is equal to zero. In this way, the region of the substrate 11 where a crack tends to propagate is reduced in volume. This can efficiently prevent the formation of a crack propagating from the bonding interface between the substrate 11 and the lead 20 to the substrate 11. In the semiconductor device A10, the terminal portion 22 overlaps with the first edge 111A of the obverse surface 111 of the substrate 11 as viewed in the thickness direction z. This serves to prevent the occurrence of a crack propagating from the bonding interface between the substrate 11 and the lead 20 to the substrate 11 and to avoid an increase in the dimension of the semiconductor device A10 in the second direction y.

The bonding layer 12 is electrically insulating. For the semiconductor device A10 provided with a plurality of leads 20, a plurality of die pad portions 21 are bonded to the obverse surface 111. The bonding layer 12 of this configuration prevents short-circuiting between adjacent die pad portions 21 even if the die pad portions 21 are arranged at minimum intervals.

Further, the bonding layer 12 is made of a material containing resin. Thus, the bonding layer 12 has a relatively large linear expansion coefficient. This serves to reduce the thermal stress at the interface between the substrate 11 and the bonding layer 12, among the thermal stresses occurring at the bonding interfaces between the substrate 11 and the leads 20. Consequently, cracking propagating to the substrate 11 can be more efficiently prevented.

The obverse surface 111 has the first edge 111A longer than the second edges 111B. The plurality of die pad portions 21 include a first pad portion 21A and second pad portions 21B located next to the first pad portion 21A. In this case, the second pad portions 21B can be located next to the first pad portion 21A in the first direction x. In addition, in a case where the terminal portion 22 is separated into one connected to the first pad portion 21A and ones connected to the second pad portion 21B, these terminal portions 22 can be arranged along the first direction x. In this way, the terminal portions 22 can be disposed without being mixed.

When the semiconductor device A10 is provided with a plurality of separate terminal portions 22, there are a plurality of connecting edges 211A each on the mounting surface 211 of the die pad portion 21. With the separate terminal portions 22 arranged along the first direction x, the connecting edges 211A are arranged along the first direction x. In this case, the effect of preventing the formation of a crack propagating to the substrate can be achieved for all the connecting edges 211A by satisfying the condition where the distance d2 from the first edge 111A of the obverse surface 111 to the outer edge of the bonding layer 12 in the second direction y is shorter than the distance d1 shown in FIGS. 10 and 13. The semiconductor device A10 including a plurality of leads 20 can efficiently prevent the occurrence of a crack propagating through the substrate 11.

In the case described above, the semiconductor elements 31 include the first elements 31A bonded to the first pad portion 21A and the second elements 31B bonded to the second pad portions 21B. The first elements 31A are arranged along the first direction x. The first elements 31A have a smaller linear expansion coefficient than the first pad portion 21A. Hence, the thermal expansion and contraction of the first pad portion 21A in the first direction x can be restricted by the first elements 31A. This can consequently reduce the thermal strain occurring in the first pad portion 21A in the first direction X. Reducing the thermal strain in the first pad portion 21A serves to prevent the occurrence of a crack propagating from the bonding interface between the substrate 11 and the leads 20 to the substrate 11.

The semiconductor device A10 includes a plurality of protection elements 32 electrically bonded to the first pad portion 21A. The protection elements 32 are arranged along the first direction x and spaced apart from the first elements 31A in the second direction y. The protection elements 32 have a smaller linear expansion coefficient than the first pad portion 21A. Hence, the thermal expansion and contraction of the first pad portion 21A in the first direction x and the second direction y are restricted by the first elements 31A and the protection elements 32. This can consequently reduce the thermal strain occurring in the first pad portion 21A in the first direction x and the second direction y.

The semiconductor device A10 also includes a sealing resin 50 covering a portion of each lead 20 and the semiconductor elements 31. The sealing resin 50 is in contact with the first edge 111A and the second edges 111B of the obverse surface 111. As a result, an anchoring effect is produced on the substrate 11 against the sealing resin 50. This is effective for preventing the detachment of the sealing resin 50 from the substrate 11.

The substrate 11 has the reverse surface 112 facing away from the obverse surface 111 in the thickness direction z. The reverse surface 112 is exposed from the sealing resin 50. This serves to improve the heat dissipation of the semiconductor device A10.

### Second Embodiment

With reference to FIGS. 17 to 20, a semiconductor device A20 according to a second embodiment of the present disclosure will be described. In these figures, components that are identical or similar to those of the semiconductor device A10 described above are denoted by the same reference numerals, and overlapping descriptions may be omitted. For convenience of description, FIG. 17 shows the sealing resin 50 as transparent. In FIG. 17, the sealing resin 50 is indicated by phantom lines.

The semiconductor device A20 differs from the semiconductor device A10 in the configurations of the plurality of leads 20.

As shown in FIGS. 17, 18, and 20, the die pad portion 21 of each lead 20 extends across the first edge 111A of the obverse surface 111 of the substrate 11. That is, the die pad portion 21 of each lead 20 has a portion extending beyond the obverse surface 111 as viewed in the thickness direction z. In addition, the terminal portion 22 of each lead 20 is located outside the obverse surface 111 as viewed in the thickness direction z. As shown in FIG. 19, the bonding layer 12 is in contact with the first edge 111A of the obverse surface 111. Thus, the distance d2 from the first edge 111A to the outer edge of the bonding layer 12 in the second direction y is equal to zero as viewed in the thickness direction z.

### Variation of Second Embodiment

The following describes a semiconductor device A21 according to a variation of the semiconductor device A20 with reference to FIG. 21. FIG. 21 shows a portion corresponding to that shown in FIG. 19.

As shown in FIG. 21, in the semiconductor device A21, the bonding layer 12 extends across the first edge 111A of the obverse surface 111 of the substrate 11. In the semiconductor device A21, the bonding layer 12 is in contact with the first edge 111A. Thus, the distance d2 from the first edge 111A to the outer edge of the bonding layer 12 in the second direction y is equal to zero as viewed in the thickness direction z.

Next, the advantages of the semiconductor device A20 will be described.

The semiconductor device A20 includes a substrate 11 having an obverse surface 111, a lead 20 having a die pad portion 21 and a terminal portion 22, and a bonding layer 12 disposed between the obverse surface 111 and the die pad portion 21. The obverse surface 111 has a first edge 111A extending in the first direction x and a second edge 111B extending in the second direction y. As viewed in the thickness direction z, the terminal portion 22 protrudes outward from the obverse surface 111 relative to the first edge 111A. The distance d2 from the first edge 111A to the outer edge of the bonding layer 12 in the second direction y is shorter than the distance d1 from the second edge 111B to the outer edge of the bonding layer 12 in the first direction x. The semiconductor device A20 can therefore prevent the formation of a crack propagating from the bonding interface between the substrate 11 and the lead 20 to the substrate 11. In addition, the semiconductor device A20 has a configuration in common with the semiconductor device A10, thereby achieving the same effect as the semiconductor device A10.

The die pad portion 21 extends across the first edge 111A of the obverse surface 111. This allows setting the distance d2 from the first edge 111A to the outer edge of the bonding layer 12 in the second direction y to zero, more easily than in the semiconductor device A10. In this way, the region of the substrate 11 in which a crack tends to propagate is reduced in volume. This can efficiently prevent the formation of a crack propagating from the bonding interface between the substrate 11 and the lead 20 to the substrate 11.

In addition, the connecting edge 211A (see FIG. 18) of the mounting surface 211 of the die pad portion 21 is located outside the obverse surface 111 as viewed in the thickness direction z. This means that the connecting edge 211A, which is where thermal strain in the lead 20 tends to concentrate, is located farther from the outer edge of the bonding layer 12, which is the edge nearest to the outer edge in the thickness direction z. As compared with the semiconductor device A10, this is more effective for reducing the concentration of the thermal stress at the outer edge. This can efficiently prevent the formation of a crack propagating from the bonding interface between the substrate 11 and the lead 20 to the substrate 11.

In the semiconductor device A21, the bonding layer 12 extends across the first edge 111A of the obverse surface 111 as shown in FIG. 21. This ensures that the distance d2 from the first edge 111A to the outer edge of the bonding layer 12 in the second direction y is set to zero.

### Third Embodiment

With reference to FIG. 22, a semiconductor device A30 according to a third embodiment of the present disclosure will be described. In these figures, components that are identical or similar to those of the semiconductor device A10 described above are denoted by the same reference numerals, and overlapping descriptions may be omitted. For convenience of description, FIG. 22 shows the sealing resin 50 as transparent. In FIG. 22, the sealing resin 50 is indicated by phantom lines.

Unlike the semiconductor device A10 described above, the semiconductor device A30 does not include the protection elements 32 and the seventh wires 47.

As shown in FIG. 22, the die pad portions 21 of the leads 20 are without the protection elements 32 electrically bonded thereto. This configuration is applicable on condition that the semiconductor elements 31 are MOSFETs built with freewheel diodes and that a relatively low direct-current power is inputted to the terminal portion 22 of the first lead 20A and the ground terminals 23. The first elements 31A are arranged along a direction that is orthogonal to the thickness direction z and is inclined relative to the first direction x and the second direction y.

Next, the advantages of the semiconductor device A30 will be described.

The semiconductor device A30 includes a substrate 11 having an obverse surface 111, a lead 20 having a die pad portion 21 and a terminal portion 22, and a bonding layer 12 disposed between the obverse surface 111 and the die pad portion 21. The obverse surface 111 has a first edge 111A extending in the first direction x and a second edge 111B extending in the second direction y. As viewed in the thickness direction z, the terminal portion 22 protrudes outward from the obverse surface 111 relative to the first edge 111A. The distance d2 from the first edge 111A to the outer edge of the bonding layer 12 in the second direction y is shorter than the distance d1 from the second edge 111B to the outer edge of the bonding layer 12 in the first direction x. The semiconductor device A30 can therefore prevent the formation of a crack propagating from the bonding interface between the substrate 11 and the lead 20 to the substrate 11. In addition, the semiconductor device A30 has a configuration in common with the semiconductor device A10, thereby achieving the same effect as the semiconductor device A10.

The semiconductor elements 31 include the first elements 31A bonded to the first pad portion 21A (the first lead 20A) and the second elements 31B bonded to the second pad portions 21B (the second leads 20B). The first elements 31A are arranged along a direction that is orthogonal to the thickness direction z and is inclined relative to the first direction x and the second direction y. Hence, the thermal expansion and contraction of the first pad portion 21A in the first direction x and the second direction y can be restricted by the first elements 31A. This can consequently reduce the thermal strain occurring in the first pad portion 21A in the first direction x and the second direction y.

The present disclosure are not limited to the embodiments described above. The specific configuration of each part according to the present disclosure may suitably be designed and changed in various manners.

The present disclosure includes the embodiments described in the following clauses.

Clause 1. A semiconductor device comprising:
a substrate including an obverse surface facing in a thickness direction;
a lead including a die pad portion bonded to the substrate and a terminal portion connected to the die pad portion;
a semiconductor element bonded to the die pad portion; and
a bonding layer interposed between the obverse surface and the die pad portion,
wherein the obverse surface includes a first edge extending in a first direction orthogonal to the thickness direction and a second edge extending in a second direction orthogonal to the thickness direction and the first direction,
as viewed in the thickness direction, the terminal portion protrudes outward from the obverse surface relative to the first edge, and
a distance from the first edge to an outer edge of the bonding layer in the second direction is shorter than a distance from the second edge to an outer edge of the bonding layer in the first direction.

Clause 2. The semiconductor device according to Clause 1, wherein the die pad portion extends across the first edge.

Clause 3. The semiconductor device according to Clause 2, wherein the bonding layer extends across the first edge.

Clause 4. The semiconductor device according to Clause 1, wherein the terminal portion overlaps with the first edge as viewed in the thickness direction.

Clause 5. The semiconductor device according to any one of Clauses 1 to 4, wherein the bonding layer is in contact with the first edge.

Clause 6. The semiconductor device according to any one of Clauses 1 to 5, wherein the bonding layer is electrically insulating and made of a material containing a resin.

Clause 7. The semiconductor device according to any one of Clauses 1 to 6, wherein the first edge is longer than the second edge.

Clause 8. The semiconductor device according to Clause 7, wherein the die pad portion includes a first pad portion and a second pad portion next to the first pad portion in the first direction,
the semiconductor element includes a plurality of first elements bonded to the first pad portion and a second element bonded to the second pad portion, and
the second element is electrically connected to one of the plurality of first elements.

Clause 9. The semiconductor device according to Clause 8, wherein the plurality of first elements are electrically bonded to the first pad portion, and
the second element is electrically bonded to the second pad portion.

Clause 10. The semiconductor device according to Clause 9, wherein the plurality of first elements are arranged along the first direction.

Clause 11. The semiconductor device according to Clause 10, further comprising a plurality of protection elements electrically bonded to the first pad portion,
wherein the plurality of protection elements are electrically connected to the plurality of first elements, respectively.

Clause 12. The semiconductor device according to Clause 11, wherein the plurality of protection elements are arranged along the first direction and spaced apart from the plurality of first elements in the second direction.

Clause 13. The semiconductor device according to any one of Clauses 8 to 12, further comprising a ground terminal electrically connected to the second element,
wherein the ground terminal is located opposite to the first pad portion in the first direction with respect to the second pad portion.

Clause 14. The semiconductor device according to any one of Clauses 1 to 13, further comprising an IC that drives the semiconductor element,
wherein the IC overlaps with the obverse surface as viewed in the thickness direction.

Clause 15. The semiconductor device according to Clause 14, wherein the IC is located opposite to the terminal portion in the second direction with respect to the die pad portion.

Clause 16. The semiconductor device according to any one of Clauses 1 to 15, further comprising a sealing resin covering a portion of the lead and the semiconductor element,
wherein the sealing resin is in contact with the first edge and the second edge.

Clause 17. The semiconductor device according to Clause 16, wherein the substrate includes a reverse surface facing away from the obverse surface in the thickness direction, and
the reverse surface is exposed from the sealing resin.

### REFERENCE NUMERALS

A10, A20, A30: Semiconductor device 11: Substrate
111: Obverse surface 111A: First edge
111B: Second edge 112: Reverse surface
12: Bonding layer 20: Lead
20A: First lead 20B: Second lead
21: Die pad portion 21A: First pad portion
21B: Second pad portion 211: Mounting surface
211A: Connecting edge 22: Terminal portion
221: Connecting surface 23: Ground terminal
24: Control terminal 241: Pad portion
243: First control portion 242: Power supply portion
244: Second control portion 245: Dummy portion
31: Semiconductor element 31A: First element
31B: Second element 311: First electrode
312: Second electrode 313: Gate electrode
32: Protection element 321: Anode electrode
322: Cathode electrode 33: IC
33A: First IC 33B: Second IC
34: Diode 39: Conductive bonding layer
41: First wire 42: Second wire
43: Third wire 44: Fourth wire
45: Fifth wire 46: Sixth wire
47: Seventh wire 50: Sealing resin
51: Top surface 52: Bottom surface
53: First side surface 54: Second side surface
55: Recessed portion 60: Dummy terminal
d1, d2: Dimension L1, L2: Length
z: Thickness direction x: First direction
y: Second direction

1. A semiconductor device comprising:
a substrate including an obverse surface facing in a thickness direction;
a lead including a die pad portion bonded to the substrate and a terminal portion connected to the die pad portion;
a semiconductor element bonded to the die pad portion; and
a bonding layer interposed between the obverse surface and the die pad portion,
wherein the obverse surface includes a first edge extending in a first direction orthogonal to the thickness direction and a second edge extending in a second direction orthogonal to the thickness direction and the first direction,
as viewed in the thickness direction, the terminal portion protrudes outward from the obverse surface relative to the first edge, and
a distance from the first edge to an outer edge of the bonding layer in the second direction is shorter than a distance from the second edge to an outer edge of the bonding layer in the first direction.

2. The semiconductor device according to claim 1, wherein the die pad portion extends across the first edge.

3. The semiconductor device according to claim 2, wherein the bonding layer extends across the first edge.

4. The semiconductor device according to claim 1, wherein the terminal portion overlaps with the first edge as viewed in the thickness direction.

5. The semiconductor device according to claim 1, wherein the bonding layer is in contact with the first edge.

6. The semiconductor device according to claim 1, wherein the bonding layer is electrically insulating and made of a material containing a resin.

7. The semiconductor device according to claim 1, wherein the first edge is longer than the second edge.

8. The semiconductor device according to claim 7, wherein the die pad portion includes a first pad portion and a second pad portion next to the first pad portion in the first direction,
the semiconductor element includes a plurality of first elements bonded to the first pad portion and a second element bonded to the second pad portion, and
the second element is electrically connected to one of the plurality of first elements.

9. The semiconductor device according to claim 8, wherein the plurality of first elements are electrically bonded to the first pad portion, and
the second element is electrically bonded to the second pad portion.

10. The semiconductor device according to claim 9, wherein the plurality of first elements are arranged along the first direction.

11. The semiconductor device according to claim 10, further comprising a plurality of protection elements electrically bonded to the first pad portion,
wherein the plurality of protection elements are electrically connected to the plurality of first elements, respectively.

12. The semiconductor device according to claim 11, wherein the plurality of protection elements are arranged along the first direction and spaced apart from the plurality of first elements in the second direction.

13. The semiconductor device according to claim 8, further comprising a ground terminal electrically connected to the second element,
wherein the ground terminal is located opposite to the first pad portion in the first direction with respect to the second pad portion.

14. The semiconductor device according to claim 1, further comprising an IC that drives the semiconductor element,
wherein the IC overlaps with the obverse surface as viewed in the thickness direction.

15. The semiconductor device according to claim 14, wherein the IC is located opposite to the terminal portion in the second direction with respect to the die pad portion.

16. The semiconductor device according to claim 1, further comprising a sealing resin covering a portion of the lead and the semiconductor element,
wherein the sealing resin is in contact with the first edge and the second edge.

17. The semiconductor device according to claim 16, wherein the substrate includes a reverse surface facing away from the obverse surface in the thickness direction, and
the reverse surface is exposed from the sealing resin.
